(19) United States
(12) Patent Application Publication
(10) Pub. No.: US 2022/0064394 A1
(43) Pub. Date: Mar. 3, 2022

(54) MULTILAYER FILM WITH BIOMOLECULE BASED BARRIER COATING

(71) Applicant: TAGHLEEF INDUSTRIES INC., Newark, DE (US)

(72) Inventors: Walter NOSOTTI, Cernusco Sul Naviglio (IT); Stefano FARRIS, Cermenate (IT); Duncan KIM, Terre Haute, IN (US)

(21) Appl. No.: 17/466,698

(22) Filed: Sep. 3, 2021

Related U.S. Application Data
(60) Provisional application No. 63/074,236, filed on Sep. 3, 2020.

(51) Int. Cl. C08J 7/04; C08J 7/043; C08J 7/048; C23C 14/20; C23C 14/24

(52) U.S. Cl. CPC C08J 7/0423; C08J 7/043; C08J 7/048; C23C 14/20; C08J 2323/12; C08J 2405/06; C08J 2429/04; C08J 2323/06; C23C 14/24

(57) ABSTRACT

The invention relates to a multilayer film including a substrate film, a biopolymer-based gas and/or water vapor barrier coating and optionally additional layers such as metal or metal oxide barrier layers and so-called primers that is applied to any one film layer to promote the adhesion another film layer or to printing inks, that can be used for many different applications, in particular the food and biomedical fields.

### CROSS-REFERENCE TO RELATED APPLICATIONS

This non-provisional utility application claims the benefit under 35 U.S.C. § 119(e) of U.S. Provisional Patent Application Ser. No. 63/074,236 filed on Sep. 3, 2020 and entitled MULTILAYER FILM WITH BIOMOLECULE BASED BARRIER COATING, the entire disclosure of which is incorporated by reference herein.

### FIELD OF THE INVENTION

The invention relates to a multilayer film comprising a substrate film, and a biopolymer-based gas and/or water vapor barrier coating, that is applied to any one film layer to promote the adhesion another film layer or to printing inks in addition to oxygen barrier. The multilayer film of this invention can be used for many different applications, in particular the food and biomedical fields. In certain embodiments, the multilayer film comprises a substrate film that consists essentially of a polyolefin (e.g., polyethylene, polypropylene), or a polyester, in particular an aliphatic polyester that may be based on renewable resources (biobased polymer like polylactic acid) or on biodegradable polymers like polylactic acid, polyhydroxy alkanoates or polyesters comprising aliphatic diols and/or aliphatic dicarboxylic acids, herein commonly addressed as “bioplastics”. In certain embodiments the multilayer film may comprise one or more additional coating layers, such as metal layers, transparent metal oxide layers, additional protective coatings, printing, or the like.

Furthermore, the invention relates to a biopolymer-based barrier coating as defined above, capable of giving the multi-layer plastic laminate properties of a stable barrier to gases and/or vapors, e.g., O₂, that do not change over time as a function of external stimuli. In such applications it has been found the use of a primer may further promote adhesion between the biopolymer-based coating and the substrate.

### BACKGROUND OF THE INVENTION

In the packaging sector, in particular film packaging for food, a film with a multilayer laminate structure is largely used where the individual layers vary in terms of material and chemical and physical properties, and wherein each layer has the purpose of providing certain features for the packaging film. Among the most widespread solutions of this packaging is that formed by a plastic film substrate, such as made of for example a polyolefin, designed to give mechanical strength to the packaging structure on which are then applied one or more coatings with lower thickness, such as for example coatings based on PVOH (polyvinyl alcohol), EVOH (ethylene-vinyl alcohol), PVDC (polyvinylidene chloride), acrylic polymers or hybrid coatings (e.g., polyvinyl alcohol+metal alkoxide), to give barrier properties to i.a., gases or moisture.

In certain embodiments wherein the substrate is chemically different from subsequently applied coatings, it may be necessary to apply interjacent layers of so-called primers as adhesive layers, in order to facilitate or promote adhesion/anchorage between substrate film and coating, and between the various subsequent coatings.

In particular, water-based coatings are currently preferred in that they are particularly environmentally friendly but may be difficult to spread and anchor on polyolefin substrates, e.g., PE or PP and thus adhesive compounds/intermediates may be useful. There is an ongoing need to find gas and/or vapor barrier coating agents, more effective and reliable and even safer for human health, which are also an environmentally friendly alternative from the point of view of the production process and from the point of view of the environmental protection and their sourcing from renewable resources. In addition, there is also the current need in the packaging sector to preserve natural and fossil resources by creating yet lighter packaging with the same final performances, in light of new trends in reduced environmental impact.

All references cited herein are incorporated herein by reference in their entireties.

### BRIEF SUMMARY OF THE INVENTION

The invention provides, for example, a multilayer film comprising: a substrate film having an inner and an outer face, comprising a base film and optionally a metal or metal oxide barrier coating deposited with its inner face on the outer face of the base film and its outer face forming the outer face of the substrate film, a biopolymer coating layer disposed on the outer side of the substrate film; wherein the outer face of the substrate film provides a surface tension suitable for adhesion to the biopolymer, and wherein said multilayer film has gas and/or vapor barrier properties The invention provides, for example, a multilayer film wherein the biopolymer coating layer exhibits adhesion to the substrate film after common physical-chemical pre-treatment used to activate the surface selected from the group of pre-treatment methods consisting of corona discharge, plasma, and flame treatment. The invention provides, for example, a multilayer film wherein the biopolymer coating layer exhibits adhesion to the substrate film after application of a primer. The invention provides, for example, a multilayer film wherein the multilayer film provides a barrier to permeation of gases selected from the group consisting of oxygen, nitrogen, carbon dioxide, moisture, and combinations thereof. The invention provides, for example, a multilayer film wherein the multilayer film exhibits oxygen barrier and moisture barrier properties. The invention provides, for example, a multilayer film wherein the base film comprises a polymer selected from the group consisting of polyolefins, bioplastics, polyamides, polyesters, and layered combinations thereof. The invention provides, for example, a multilayer film wherein the base film comprises a polymer or polymer blend which is one or more polyolefins selected from the group consisting of polypropylene homopolymer, polyethylene including high density polyethylene, propylene/ethylene copolymers, propylene/ethylene/butene-1 terpolymers, maleated polypropylene and incompatible blends of a polypropylene with a polyethylene or another poly alpha-olefin or incompatible blends of polyethylene with another poly alpha-olefin, and combinations thereof. The invention provides, for example, a multilayer film wherein the base film comprises between one and seven coextruded layers, with at least one layer being polyamide or EVOH, and the majority of layers comprising one or more polyolefins. The invention provides, for example, a multilayer film wherein the base film comprises one or more layers of polyolefins, a tie layer adjacent with its inside surface contiguous with the outside surface of the polyolefin layer or layers, and a polyamide layer contiguous with the outside surface of the tie layer. The invention provides, for example, a multilayer film wherein the base film comprises at least one core layer consisting essentially of polypropylene homopolymer, an inner skin layer consisting of polypropylenes selected from a group comprising propylene homopolymers, copolymers or terpolymers or maleated polypropylenes or blends thereof contiguous with the inner surface of the core layer, optionally with an additional inner tie layer interjacent between the inner skin and inner surface of the core layers, a tie layer consisting of maleated polypropylene or a blend of one or several polypropylenes with polymers selected from a group comprising maleated polypropylenes and copolymers of ethylene with one or several comonomers selected from a group comprising vinyl acetate, methyl or butyl acrylate, vinyl alcohol or acrylic acid, contiguous with the outer surface of the core layer, and an outer skin layer consisting of one or several polyamides selected from a group comprising amorphous and semi-crystalline polyamides contiguous with the outer surface of the outer tie layer. The invention provides, for example, a multilayer film wherein the base film comprises one or more polymers selected from the group consisting of polyhydroxy alkanoates, polylactic acid (PLA), polyhydroxy alkanoates and polyesters comprising aliphatic diols and/or aliphatic dicarboxylic acids and copolymers thereof, cellulose-based bioplastics, starch, and combinations mixtures or blends thereof. The invention provides, for example, a multilayer film wherein the biopolymer coating layer comprises polysaccharides, polymeric sugar carboxylic acid, and their chemically modified bio-based and/or biodegradable derivatives such as partially methylated and/or partially amidated sugar carboxylic polymers. The invention provides, for example, a multilayer film wherein the biopolymer coating layer comprises poly uronic acid, poly galacturonic acid, and their chemically modified bio-based and/or biodegradable derivatives. The invention provides, for example, a multilayer film wherein the biopolymer coating layer comprises pectin, amidated pectin, methylated pectin, amidated and methylated pectin, pectin ester, pectin ester amide, pullulan, chitosan, and combinations thereof. The invention provides, for example, a multilayer film wherein the biopolymer coating layer comprises ethylenevinyl alcohol (EVOH) and/or polyvinyl alcohol (PVOH) as structuring agent, and/or a metal alkoxide as reinforcing agent. The invention provides, for example, a multilayer film wherein solvents selected from the group consisting of water, alcohols, ketones, and mixtures thereof are suitable to facilitate the application of the biopolymer coating to the substrate. The invention provides, for example, a multilayer film wherein the solvent to facilitate the application of the biopolymer coating is water. The invention provides, for example, a multilayer film wherein the biopolymer coating layer comprises amidated and/or methylated biopolymers of pectin. The invention provides, for example, a multilayer film wherein the biopolymer coating layer comprises esterified biopolymers of pectin. The invention provides, for example, a multilayer film wherein the biopolymer coating layer comprises esterified pectin, amidated pectin, methylated pectin, amidated and methylated pectin, esterified amidated pectin, that contains methyl carboxylic groups, amide groups, and combinations thereof. The invention provides, for example, a multilayer film wherein the biopolymer coating layer comprises amidated pectin, methylated pectin, amidated, methylated pectin, and combinations thereof which has a degree of amidation (DA) comprised between 15 and 65 (DA), more preferably comprised between 20 and 40 (DA). The invention provides, for example, a multilayer film wherein the biopolymer coating layer comprises pectin with a degree of esterification (DE) between 7 and 75 or a degree of amidation (DA) between 15 and 65. The invention provides, for example, a multilayer film wherein the biopolymer coating layer comprises pectin which has a DE between 20 and 40, and a DA between 10 and 30. The invention provides, for example, a multilayer film wherein the biopolymer coating layer comprises pectin with about 30-40% of all carboxylate groups methylated and 10-20% amidated. The invention provides, for example, a multilayer film wherein the biopolymer coating layer comprises pectin with between 40 and 60%, preferably 45 and 55% of the carboxylic acid groups being methylated and/or amidated. The invention provides, for example, a multilayer film wherein a metal layer is deposited on the outer face of the biopolymer layer. The invention provides, for example, a multilayer film wherein the metal layer is deposited on the outer face of the biopolymer layer using vacuum deposition technology. The invention provides, for example, a multilayer film wherein a metal oxide layer is deposited on the outer face of the biopolymer layer. The invention provides, for example, a multilayer film wherein the metal oxide layer is deposited on the outer face of the biopolymer layer using vacuum deposition technology. The invention provides, for example, a multilayer film wherein ink is disposed on the biopolymer coating layer. The invention provides, for example, a multilayer film wherein first a print primer, then inks are disposed on the biopolymer coating layer. The invention provides, for example, a multilayer film wherein the multilayer film comprises additional optional layers selected from the group consisting of metal, transparent metal oxide, additional protective coatings, printing, embossing, holographics, and combinations thereof. The invention provides, for example, a multilayer film wherein the multilayer film comprises additional alternating layers of metal or metal oxides, preferably AlOx, and biopolymer. The invention provides, for example, a multilayer film wherein the biopolymer coating layer provides for a function selected from the group consisting of adhesion, protection, barrier to permeation of gases, and combinations thereof.

### DETAILED DESCRIPTION OF THE INVENTION

The objective of the invention is to overcome, at least in part, the disadvantages of the prior art by providing a gas and/or water vapor barrier coating that is compatible both with the polymer of the plastic substrate and with the various coatings used in the field of packaging films such as printings or additional barrier or protective or other functional layers, for example in food and medical packaging applications.

A further objective is to provide a gas and/or water vapor barrier coating as defined above that allows an effective anchorage of metal-based coatings (conventional metallization and deposition of transparent metal oxides) on polyolefin substrates, e.g., PE or PP, or on bioplastic-based substrates.

Another objective is to obtain environmentally friendly and also lighter packaging with improved performance.

At least one of these objectives is achieved by the biopolymer-based gas and/or water vapor barrier coatings according to this invention. A subject of the invention relates to the use of, e.g., an amidated and/or methylated biopolymer, i.e., containing —C(═O)—CH₃ and/or —C(═O)—NH₂ groups derived from part of the carboxylic acid groups, as a gas and/or water vapor barrier coating to be deposited (spread) directly on substrates which may be plastic films, preferably polyolefin (e.g., polyethylene, polypropylene or the like), or bioplastics-based films.

### Substrate

In exemplary embodiments as disclosed herein, a substrate may comprise, for example, a polyolefin, a bioplastic, a polyamide, or layered combinations thereof. Reference to a “polyolefin” or “polyolefin substrate” in this application, unless stated otherwise, means a polymer blend or a substrate that consists primarily of one or several of homopolymers, copolymers or terpolymers in which the predominant monomer components, by weight, are olefins. Preferably, the polyolefin substrate may include one or more polyolefins from the group consisting of polypropylene homopolymer, polyethylene including high density polyethylene, propylene/ethylene copolymers, propylene/ethylene/butene-1 terpolymers, maleated polypropylene and incompatible blends of a polypropylene with a polyethylene or another poly alpha-olefin or incompatible blends of polyethylene with another poly alpha-olefin or combinations thereof. Polyolefins are thermoplastic resins polymerized from ethylenically unsaturated hydrocarbons. The two principal ethylenically unsaturated hydrocarbons are ethylene and propylene. Ethylene is the raw material for making polyethylene (PE) and ethylene copolymer resins and propylene is the raw material for making polypropylene (PP) and propylene copolymer resins. Polyolefin resins are classified as thermoplastics, which means that they can be melted, solidified, and melted again.

In another embodiment, the substrate film may comprise one or several layers of polyolefins, a tie layer adjacent with its inside surface contiguous with the outside surface of the polyolefin layer or layers, and a polyamide layer contiguous with the outside surface of the tie layer. In a preferable embodiment the substrate film comprises at least one core layer consisting essentially of polypropylene homopolymer, an inner skin layer, or an inner skin layer and an interjacent tie layer between the skin and the core layers, all consisting of polypropylenes selected from a group comprising propylene homopolymers, copolymers or terpolymers or maleated polypropylenes or blends thereof contiguous with the inner surface of the core layer, a tie layer consisting of maleated polypropylene or a blend of one or several polypropylenes with polymers selected from a group comprising polypropylenes, maleated polypropylenes and copolymers of ethylene with one or several comonomers selected from a group comprising vinyl acetate, methyl or butyl acrylate, vinyl alcohol or acrylic acid, contiguous with the outer surface of the core layer, and an outer skin layer consisting of one or several polyamides selected from a group comprising amorphous and semicrystalline polyamides such as PA-6.66, PA-MXD6, PA-61/6T or PA-6-3T.

Reference to “propylene polymer,” unless indicated otherwise, means a propylene homopolymer (“Homo PP”), or a copolymer (“Copo”) or a terpolymer (“Terpo”) in which the predominant monomer component, by weight, is propylene.

Reference to “propylene terpolymer,” unless indicated otherwise, means a terpolymer comprising propylene (“C3”), ethylene (“C2”), and butene-1 (“C4”) monomer units in which propylene is the predominant monomer unit by weight.

Reference to “propylene copolymer,” unless indicated otherwise, means a copolymer comprising propylene (“C3”), and ethylene (“C2”), or butene-1 (“C4”) monomer units in which propylene is the predominant monomer unit by weight.

Reference to “propylene homopolymer,” unless indicated otherwise means a homopolymer and also a propylene-ethylene copolymer in which the percentage of ethylene is so little that it doesn't adversely affect the crystallinity or other properties of the homopolymer. These copolymers are referred to as “mini-random” copolymers and have a percentage ethylene, by weight of the copolymer, of 0.8% or less.

Representative materials usable in this invention, including the supplier, are:

| Description | Trade name | Supplier |
|---|---|---|
| Homo PP | FF030F2 | Braskem |
| Copo (2.5% C2) | R08G-00 | Ineos |
| Copo (2.5% C2) | DS6D21 | Braskem |
| Copo (4.5% C2) | DS6D82 | Braskem |
| Matt PP/PE blend | MT 0523 DP | Tosaf |
| Maleated Homo PP | Admer QF500A | Mitsui |
| CaCO3/PP masterbatch | PF97 | A. Schulman, affiliate |
| | | of LyondellBasell |
| Polyamide | Ultramid C33L01 | BASF |

The above list is exemplary of useable components in this invention. In addition, there are numerous suppliers of polypropylene homopolymers as well as other polyolefins usable in this invention. Such materials are used to make biaxially oriented plastic films.

The term “bioplastics” or “bioplastics substrate” as used herein is intended to identify any thermo-processable bio-based polymer including polymers derived from the fermentation products of sugars and/or oils, and/or biodegradable bioplastic, which preferably are bio-based as well as biodegradable, chosen from polyhydroxy alkanoates, like polylactic acid (PLA), polyhydroxy alkanoates and polyesters comprising aliphatic diols and/or aliphatic dicarboxylic acids an copolymers thereof, cellulose-based bioplastics, starch or combinations, mixtures or blends thereof.

In the current art, multiple methods exist to produce bioplastics from renewable biomass such as carbohydrate, protein or polyesters. Starch and cellulose are common starting carbohydrates for bioplastics. Starch, when mixed with certain additives such as various glycols, oligoglycols, glycerol and sugar alcohols, can be processed thermo-plastically. The addition of other biodegradable polymers, in particular biodegradable polyesters, can improve its malleability. Starch based bioplastics account for approximately half of the bioplastics in the market. Despite their abundance and versatility, significant challenges still exist to improve the physical properties of starch-based composites. Moreover, many starch-based plastics show less favored biodegradability. Cellulose, a structural component in plant cell wall, is a polysaccharide consisting of a linear chain of several hundred to many thousands of (C₆H₁₀O₅)ₙ units. Cellulose film has a long history of application in various industries. The hydroxyl groups of cellulose can partially or fully react with various reagents to produce cellulose esters which can then be produced into bioplastic films. The main disadvantage of cellulose based bioplastic is its hydrophilic nature. Very often, the plastic made from cellulose possess low water vapor barrier and have poor process ability. It is also comparatively brittle, has limited long-term stability and poor other mechanical properties.

Another commonly used plant based raw material to make a bioplastics is the polyester Polylactic Acid (PLA). PLA derived from lactic acid which is a byproduct from the fermentation of dextrose which is in turn derived from many plants, mainly corn. It is a thermoplastic, biodegradable aliphatic polyester having potential for packaging applications. In certain embodiments herein, the PLA is used as a biodegradable biaxially oriented polylactic acid (BoPLA) substrate film. The lactic acid monomers are either directly poly-condensed or undergo ring-opening polymerization of lactide to form PLA pellets. PLA is the first bio-based polymer commercialized on a large scale and replaces high-density polyethylene, low-density polyethylene (LDPE), and polyethylene terephthalate (PETP) as packaging material in certain degree. Among representative usable materials are polylactic acid (PLA) polymers which are provided by Natureworks.

### Biopolymer Barrier Coating

The biopolymer barrier coating as disclosed herein has high oxygen barrier properties. In certain embodiments, the invention provides methods for obtaining coatings of natural origin with innovative properties and their applications on substrates. According to certain embodiments of the invention, an optimal adhesion to the substrates is reached thanks to the selection of specific natural biopolymers, such as, for example, polysaccharides, sugar carboxylic acid (or: uronic acid) polymers like polygalacturonic acid, and their chemically modified bio-based and/or biodegradable derivatives such as partially methylated and/or partially amidated sugar carboxylic polymers, and the appropriate formulation (solid content, viscosity) of the coating solution. In certain embodiments, pectin and/or derivatives thereof are used as the polysaccharides. In certain embodiments, to obtain the coating subject of this invention, a synthetic molecule may be used, such as ethylenevinyl alcohol (EVOH) and polyvinyl alcohol (PVOH) as structuring agent, and a metal alkoxide as reinforcing agent. Solvents like water, or alcohols or ketones and mixtures thereof are suitable to facilitate the application of the biopolymer coating to the substrate. In certain embodiments, the solvent may be water.

In certain embodiments, biopolymer barrier coatings as disclosed herein exhibit gas and/or water vapor barrier properties, such as high oxygen barrier and moisture barrier properties, and exhibit strong adhesion to the substrates after common physical-chemical pre-treatment used to activate the surface (corona discharge, plasma, flame treatment), in particular if applied to a polyolefin surface. In other embodiments, particularly homogeneous, essentially defect-free coatings of outstandingly strong adhesion can be accomplished by interjection of a chemical primer between substrate and coating. In addition, the coating obtained can be defined as an environmentally friendly coating, since it comprises bio-macromolecules, and provides a low environmental impact during waste disposal.

In certain embodiments, biopolymer barrier coatings as disclosed herein may be amidated and/or methylated biopolymers based on pectin as can be extracted from fruit such as apples or fruit peels such as citrus peel; in particular such pectin may be a chemically modified pectin with respect to the native structure in that it esterified and/or amidated so that it contains for example methyl carboxylic or amide groups or both.

Preferably the pectin, modified by partial methylation and/or amidation of the carboxylic acid groups in accordance with the invention has a degree of amidation (DA) comprised between 15 and 65 percent, more preferably comprised between 20 and 40 percent. In certain embodiments, pectin, obtained from citrus or apples, has, for example, a DE (DE) between 7 and 75 percent and a DA percent between 15 and 65. Methylation is the preferred way of esterification.

In another embodiment, this modified pectin has a DE comprised between 10 and 30, and a DA comprised between 20 and 40. In certain embodiments disclosed herein, the pectin is extracted from Citrus peels, then modified with about 50% of the carboxylic acid groups being either methylated or amidated. Among these chemically modified pectins those with 30-40% of all carboxylate groups methylated and 10-20% amidated are preferred.

The formulation of the biomolecule barrier coating solution as disclosed herein provides for the use of the biopolymer in quantities comprised between about 0.1% and 15% by weight, preferably between 1% and 10% by weight, with respect to the total weight of the composition, where the part remaining to 100 being a suitable solvent such as water, a aliphatic alcohol of the formula CH3—(CH2)x—OH with x=0-3, isopropanol, isobutanol, or a ketone like acetone of methyl ethyl ketone, aliphatic ester like ethyl acetate, or mixtures thereof. The preferred solvent is water, for its low environmental impact, or solvent mixtures of water and ethanol with a water content of more than 50%, preferentially more than 75%, the remainder to 100% being ethanol. In exemplary embodiments, formulations of the disclosure may comprise a biomolecule barrier coating, such as amidated and/or methylated pectin, at a concentration of about 0.01%, about 0.02%, about 0.05%, about 0.1%, about 0.2%, about 0.3%, about 0.4%, about 0.5%, about 0.6%, about 0.7%, about 0.8%, about 0.9%, about 1%, about 2%, about 3%, about 4%, about 5%, about 6%, about 7%, about 8%, about 9%, about 10%. In exemplary embodiments, formulations of the disclosure may comprise a biomolecule barrier coating, such as amidated and/or methylated pectin, at a concentration of about 1 to 20%, of about 5% to 25%, about 10% to about 20%, or about 15% to about 18%, about 30% to about 70%, about 35% to about 65%, about 63.13%, and about 40% to about 64% w/w. In exemplary formulations of the disclosure, a biomolecule barrier coating, such as amidated and/or methylated pectin, will represent approximately 1 wt. % to 75 wt. %, preferably 2 wt. % to 30 wt. %, more preferably 5 wt. % to 20 wt. % of the formulation.

Therefore, another subject of the invention is an aqueous composition including, for example, an, pectin, pectin amide, pectin ester, pectin ester amide, pullulan, chitosan, and combinations thereof, as defined herein.

The barrier properties attributed to pectin coating can be further extended also to water vapor if, for example, an inorganic component, represented by the metal alkoxides family, is added to the formulation. In certain embodiments, an aqueous composition may also optionally contain other co-formulants such as structuring agents, e.g., polyvinyl alcohol; reinforcing agents, e.g., metal alkoxides such as, for example, aluminum tri-sec-butylate, used in the prior art for hybrid barrier coatings, in particular in case wherein the aim is to increase the gas and vapor barrier property.

In the prior art, in order to obtain sufficient adhesion of metal oxide layers to the polyolefin substrate, a plasma is generally applied, resulting in a substantial improvement of the water vapor barrier, however a limited oxygen barrier which is somewhat variable presumably due to defects in the metal oxide layer imposed by mechanical stress during processing of the metal oxide coated film. In addition, the operation of the plasma unit consumes fairly much electrical energy, thus is expensive and less environmentally friendly, and is a complex process compared to the application of the pectin-based polymer coating as a primer in accordance with the invention.

In specific embodiments the aqueous composition has the following formulation (% by weight, the remainder to 100% being solvent/dispersant):

amidated and/or methylated pectin 3%

structuring agent 5%

reinforcing agent 3%.

In certain embodiments as disclosed herein the aqueous composition comprises the amidated and/or methylated pectin-based polymer at 1% to 6%, preferably 2% to 4%; structuring agent is present at 2% to 7%, or preferably at 3% to 67%; reinforcing agent is present at 1% to 6%, or preferably at 2% to 4% by weight, the remainder to 100% being solvent/dispersant.

In addition, the use of the pectin-based polymer coating as a primer is also advantageous in that it allows the deposition of a smaller quantity of metal resulting in a lower optical density value of the metallized film as is required in certain applications where a metal layer of limited optical density is required without compromising the barrier properties.

### Application Process

The aqueous composition in accordance with the invention is then applied onto the substrate film, according to procedures known in the art, using different known methods, depending on the substrate to be coated.

For example, the preferred deposition technique is coating, which makes it possible to deposit very thin layers of the pectin-based polymer on plastic films and easy to dry perfectly, with the substrate either already formed (and optionally already mono-, bi-oriented) or newly extruded and eventually oriented together with the pectin-based polymer already applied.

In certain embodiments of the coating process an already formed substrate film is unwound from a reel, touches down on a metal roller provided with surface micro-engravings (gravure roller) that are filled with the pectin-based polymer formulated with solvents and eventual with additives (the wet coating), by this transferring part of the micro-engraving content as a layer of wet coating on the substrate. Subsequently, the micro-engravings on the gravure roller pass through a reservoir of the wet coating to replenish the transferred volume of the wet coating, with any adhering excess wet coating being scraped off by means of a so-called doctor blade. The viscosity of the wet coating, the size of the micro-engravings, and the direction of rotation of the application roller (direct or reverse) essentially determine the amount of wet coating applied to the substrate film. To eventually reduce the amount of coatings transferred to the film one or several off-set rollers can be positioned between the gravure roller and the film as is known in the art.

Subsequently, the substrate with the wet coating on its surface passes through a dryer which is a long slit where it is suspended on multiple idle rollers, with the dryer being delimited above by nozzles that blow a steady stream of heated air, e.g., at 90° C., to completely evaporate the solvent and dry the coat.

In a specific embodiment of the coating process, before entering the dryer the substrate with the wet coating on its surface passes through a narrow space where the wet coating is exposed to infrared lamps, whose action is to facilitate the evaporation of the water.

In certain embodiments the pectin-based polymer coating is applied directly to the substrate film provided that the surface to which the coating shall be applied has been modified by subjecting the film to so-called corona discharge treatment, a flame treatment or a plasma treatment to improve the wettability with the coating and the adhesion between substrate and coating. The level of treatment that is required at the time of application of the coating must be high enough to allow wetting with a so-called dyne test solution according to ASTM D2578-09 of 412 dynes or higher. Provided that the dynes level at doff of the substrate film has been >46 dynes the substrate film has been successfully subjected to coating within 7 to 10 days after its manufacturing.

In another embodiment the BoPP substrate, especially if the wettability is, or has dropped below 41 dynes pectin-based polymer coating directly on such substrates can be accomplished if the substrate is subjected to refreshing of the treatment level by passing a corona treater station immediately, in general in line with, the application of the coating.

In applications that involve the deposition of metal or metal oxide layers the pectin-based polymer coatings of this invention act at the same time as a primer for improved anchorage of such metal or metal oxide layers and, depending on the thickness of the pectin-based polymer coating, also as a barrier layer in its own right. In combining the barrier properties of the metal or metal oxide layers with the barrier properties of the pectin-based polymer coating eventual defects in any of these layers are compensated by the barrier provided by the other layer. In this way multilayer films according to this invention of superior barrier properties have been accomplished.

Examples 1 through 10 show, using different polysaccharides such as chitosan and pullulan, that these polysaccharides do provide an acceptable adhesion force, which on PP is around 0.5-0.7 N/25 mm.

As mentioned above, the deposition of the biopolymer-based polymer coatings of this invention can also be performed continuously during the extrusion of the base film (i.e., as soon as it is formed and physically stable), before the latter undergoes the process of mono-, or bi-orientation or the second transvers orientation step in a sequential biorientation process.

In certain embodiments, a coating of, for example, MAP (methylated amidated pectin) also serves another important function, namely that of acting as, for example, an oxygen barrier, as illustrated in Examples 1-3.

Without wanting to be tied to any theory, it can be assumed that this property is related to the formation of inter- and intra-molecular hydrogen bridges between the OH, ester, carboxylic acid and amide groups of the pectin-based polymers in the coatings of this invention.

Therefore, the coating based only on MAP is able to perform a double fundamental function on polyolefin substrates, and on bioplastics-based substrates, ensuring an adequate adhesion of any printing or additional layers of metal or transparent metal oxide to provide additional barrier to permeation of gases like oxygen, nitrogen or carbon dioxide, or of moisture.

Multilayer film according to this invention provides barrier not only for exclusion of oxygen from the interior of food or medicals. These multilayer films are also used as packaging materials for so-called modified atmosphere packages. The air in such packages is replaced for i.e., nitrogen or carbon dioxide and thus provides additional protection for the packed article, for example food or medicals, and the packaging material prevents loss of the replacing gas.

As mentioned above, the barrier properties attributed to pectin coating can be further extended also to water vapor if an inorganic component, represented by the metal alkoxides family, is added to the formulation.

In other embodiments the coating of, for example, MAP along with its own contribution to the barrier performance also serves as a protective layer in that it is applied on the outside of a metal or metal oxide barrier layer to protect against mechanical damage like scratches.

### Application of Additional Layers

Such coated films may subsequently be printed or coated with other functional layers, such as protective layers or additional barrier layers. In certain embodiments, metal such as aluminum and metal oxides such as aluminum oxide, AlOx with x being close to but less than 1.5, or silicon oxide, SiOx with x being close to but less than 2.0, can be deposited on the surface of the pectin-based polymer coat using vacuum deposition or sputtering technology to further improve the barrier of the multilayer film of this invention. The x in AlOx as well as in SiOx can be chosen in such a way as to obtain a transparent barrier film, provided that the substrate has been a transparent plastic film.

### Metal Coatings

According to this invention, the biopolymer coating applied directly as the primary coating to the surface of the substrate film serves to prepare the substrate for the deposition and good anchorage of subsequent coatings that would otherwise not easily adhere to the substrate. Examples of coatings that profit from improved anchorage and at the same time of improved barrier properties are metal and metal oxide layers deposited by metal evaporation, eventually in conjunction with injection of oxygen into the cloud of the metal vapor in a vacuum chamber.

In another embodiment, the pectin-based polymer coating, applied before deposition of an additional metal or metal oxide layer, comprises metal alkoxides, preferentially aluminum-based alkoxides, such as for example aluminum tri-sec.-butylate which improves the barrier increment of the pectin-based polymer coating layer.

In other embodiments of the invention the multilayer films with pectin-based polymer coating and eventually additional metal or metal oxide layers are used to produce laminates with other plastic films that also provide improved water vapor barrier values. Laminates of the metallized multilayer films reach WVTR values of lower than 0.5 g/(m²×day) as measured according to ASTM F1249, at 38° C. and R.H=90%, preferably lower than 0.2 g (m²×day).

Suitable additional barrier layers according to this invention include metal oxides like silicon oxide (SiOx) and aluminum oxide (AlOx), or aluminum (Al) metal. Metallization and metal oxide coating may be performed by physical vapor deposition and accordingly, the thickness of the metal or metal oxide layer may vary from 10 to 150 nm. In certain embodiments the deposition of metal oxide (SiOx and AlOx) can be used to produce transparent barrier films, while aluminum (Al) metal coatings produce non-transparent metallized films for, for example, food packaging.

### Primer Layer

Primers are commonly used to improve the defect-free quality/homogeneity of the application and the adhesion of printing inks and coatings to a substrate. The primers can be applied as a dispersion or as a solution. In certain embodiments herein, the primers may include, for example, polyethylenimine or “PEI” or certain polyurethane dispersions. In certain embodiments, a primer may comprise a biomolecule as disclosed herein.

In certain embodiments herein, a primer, bonding agents, or tie layers can include individually, or in mixtures, polymers of, for example, ethylene/alkyl methacrylate copolymers, ethylene/acrylic acid copolymers or ethylene/acrylic acid copolymers and salts thereof (ionomers), vinyl acetates and vinyl chlorides or acryloyl derivatives and mixtures thereof, for example styrene/butadiene, styrene/acrylonitrile, styrene/ethylene (interpolymers) styrene/alkyl methacrylate, styrene/butadiene/alkyl acrylate, styrene/butadiene/alkyl methacrylate; unsaturated monomers such as acrylonitrile/butadiene copolymers acrylate copolymers, halide copolymers and amines from acyl derivatives or acetals; cross-linked polymers derived from aldehydes on the one hand phenols, ureas, and melamines such as phenol/formaldehyde resins and cross-linked acrylic resins derived from substantial acrylates, e.g., epoxyacrylates, urethaneacrylates or polyesteracrylates and starch; polymers and copolymers of such materials as poly lactic acids and its copolymers, cellulose, polyhdyroxy alcanoates, polycaprolactone, polybutylene succinate, polymers and copolymers of N-vinylpyrroolidone such as polyvinylpyrrrolidone, and crosslinked polyvinylpyrrolidone, ethyl vinyl alcohol.

The invention is not limited to the particular embodiments previously described and illustrated in the accompanying drawings, but numerous detailed changes may be made thereto, within the reach of the person skilled in the art, without thereby departing from the scope of the invention itself, as defined in the appended claims. The invention will be illustrated in more detail with reference to the following Examples, but it should be understood that the invention is not deemed to be limited thereto.

### EXAMPLES

### Example 1

The pectin-based polymer coating according to the invention used in the tests was formulated using the following composition (% by weight):

methylated-amidated pectin (with a degree of methylation of 35% and a degree of amidation 15%) 3%.

water complement to 100%,

subsequently applied to a 3-layer BoPP film comprising a core of approx. 28 micron thickness essentially consisting of a propylene homopolymer, with 2 skin layers each of a thickness of approx. 1 micron comprising a propylene terpolymer and 1000 pp of a silica anti-blocking agent of a nominal diameter of 3.4 micron, coextruded and sequentially oriented 4.8× in machine direction, then 8.9× in transverse direction, with one surface subsequently corona treated to a level of the surface tension of 43 dynes. The treatment has been refreshed by another corona treatment before applying the coating.

The coating has been applied at a wet coat weight of 6.6 g/m² using Mayer rod #5, then dried at 115 C for 90 sec. The resulting dry coat weight has been 0.2 g/m². The coated film has been tested for the adhesive strength of the coating to the substrate film in a semi-empirical way by the tape method, using the 3M tape according to ASTM D3359 (09). The coated film “passed” the test if the adhesive tape was not able to take the coating with it when peeled off.

The coating has been repeated targeting a dry coat weight of 0.7+/−0.1 g/m²). Samples of the coated film have been tested for their oxygen permeability (Oxygen Transmission Rate—OTR), in accordance with ASTM D3985-10. The OTR was measured using Multiperm permeability meter (available from Extrasolution, Italy) and the measurements were conducted under controlled thermo-hygrometric conditions (T=23° C.; RH=0%) and with 1 atm partial pressure between the measuring cells.

The results of OTR and adhesion tests are summarized in Table 1.

### Example 2

Example 1 has been repeated dry coat weight has been 0.7 g/m² using Meyer rod #10.

OTR and adhesion have been tested as described before, the results are summarized in Table 1.

### Example 3

Example 2 has been repeated replacing the pectin-based polymer for chitosan, which is a polyglucosamine-co-N-acetyl-glucosamine with the glucosamine units being produced by de-acetylation with a degree of deacetylation of 90 and an average molecular weight of [3800-20,000]. OTR and adhesion have been tested as described before, the results are summarized in Table 1.

### Example 4

Example 2 has been repeated replacing the pectin-based polymer for pullulan, a polymaltose with an average numerical molecular weight of 200.

OTR and adhesion have been tested as described before, the results are summarized in Table 1.

### Examples 5 through 7

Multilayer film samples as described in Examples 2 through 4 have been metallized using the vapor deposition technology. The conditions have been adjusted to match an optical density of 2.8.

Samples of the film have been tested for their oxygen permeability (Oxygen Transmission Rate—OTR), in accordance with ASTM D3985-10.

The adhesion between the AlOx layers and the dry (pectin-based, chitosan, pullulan) coating layers have been tested according to the AIMCAL standard). The results of OTR and adhesion tests are summarized in Table 1.

### Examples 8 through 10

Multilayer film samples as described in Examples 2 through 4 have been subjected to the deposition of AlOx starting out with an OD before injecting oxygen (OD of the metal layer) of 0.5, and adjusting the oxygen flow to an optical density of the film of OD=0.1, using the vapor deposition technology.

Samples of the film have been tested for their oxygen permeability (Oxygen Transmission Rate—OTR), in accordance with ASTM D3985-10 after full oxidation of the AlOx layer has been accomplished (after about a week).

The adhesion between the AlOx layers and the dry (pectin-based, chitosan, pullulan) coating layers have been tested according to the AIMCAL standard). The results of OTR and adhesion tests are summarized in Table 1.

### Comparative Example 1

The pectin-based polymer coating according to the invention used in the tests was formulated using the following composition (% by weight):

94 wt. % of water was heated to 90° C. 6 wt. % of LM 101-AS powder (Pectin extracted from Citrus shells, with 35% of all carboxylate groups methylated, 15% amidated, available from CPKelco under the brand name of GENU) and intensively agitated for at least 1 hour until the powder was completely dissolved. Subsequently, the mixture was cooled down to room temperature. The viscosity has been tested to be 420 cps using the Brookfield viscometer with spindle #5 at 60 rpm.

A 3-layer BoPP film comprising a core of approx. 18.4-micron thickness essentially consisting of a propylene homopolymer, with 2 skin layers each of a thickness of approx. 0.8 micron comprising a propylene terpolymer and 1000 pp of a silica anti-blocking agent of a nominal diameter of 3.4 micron, was coextruded and sequentially oriented 4.9× in machine direction, then 9.2× in the transverse direction, with one surface subsequently corona treated.

At the time of coating test liquids of 38 dynes or lower have been found to wet the film surface according to ASTM D2578-09.

The coating solution has been applied to meet at a coat weight of 0.9±0.1 g/m² dry. The film has been dried at 115° C. for 90 sec.

### Example 11

Comparative Example 1 has been repeated, however, the pectin-based polymer coating has been applied after application of 0.1 g/m² dry of the primer PEI (Lupasol FT P, a multifunctional cationic polyethyleneimine, formula: —(CH₂—CH₂—NH)ₙ with 10<n<100,000, available from BASF) using a Mayer rod #3. Primer was dried for 90 sec at 115° C., then conditioned for 24 hours at 23° C./50% relative humidity before applying the pectin-based polymer coating.

### Example 12

Example 11 has been repeated replacing the BoPP film for Nativia NBSS 20 (BoPLA, biaxially oriented PLA film commercialized by Taghleef Industries).

### Comparative Example 2

Comparative Example 1 has been repeated replacing the BoPP film for Nativia NBSS 20 (BoPLA).

### Comparative Example 3

Comparative Example 1 has been repeated replacing the BoPP film for Nativia NBSS 20 (BoPLA).

### Example 13

Example 1 has been repeated replacing the BoPP film for a BoPP film comprising an inner skin layer comprising a terpolymer, a core layer comprising propylene homopolymer, a tie layer comprising a MAH grafted propylene homopolymer, and an outer skin layer comprising a semicrystalline polyamide.

### Comparative Example 4

Example 13 has been repeated without applying another corona treatment before application of the coating.

### Example 14

Example 13 has been repeated, however, the pectin-based polymer coating has been applied after application of 0.1 g/m² dry of the primer as in Example 11.

### Example 15

Comparative Example 1 has been repeated replacing the BoPP film for AluClear HBEL 17, a film coated with a thin transparent layer of AlOx.

### Example 16

Example 11 has been repeated replacing the BoPP film for AluClear HBEL 17.

The barrier properties and the adhesive forces between the various coating layers are summarized in Table 1, below.

TABLE 1

| | In-line | | | | | | | | | | |
|---|---|---|---|---|---|---|---|---|---|---|---|
| | treatment/ | | | | | | | | | | |
| | Metal or | | | Bio | Bio | | Metal/ | OTR | | WVTR | |
| | metal | Coat | Bio | coating | coating | | AIOx | [cc/m²/d] | | [g/m²/d] | |
| | oxide | Primer | coating | ct.wgt | anchorage | Metal/ | anchorage | Before | X10 | Before | X10 |
| Reference | coating | [g/m²dry] | [g/m2] | [g/m²] | N/25mm | AIOx | N/25mm | Gelbo | Gelbo | Gelbo | Gelbo |
| Non−coated | CT | −/− | −/− | −/− | −/− | −/− | −/− | 1580 | n.a. | 3.26 | n.a. |
| substrate | | | | | | | | | | | |
| Example 1 | CT | −/− | pectin | 0.2 | 3.5/3.0 | −/− | −/− | 1.6 | n.a. | n.a. | n.a. |
| Example 2 | CT | −/− | pectin | 0.7 +/− 0.1 | passed ⁺) | −/− | −/− | 0.30 ± 0.04 | −/− | −/− | −/− |
| Example 3 | CT | −/− | chitosan | 0.2 | passed ⁺) | | −/− | 2.5 ± 0.3 | −/− | −/− | −/− |
| Example 4 | CT | −/− | pullulan | 0.2 | passed ⁺) | | −/− | 4.8 ± 0.6 | −/− | −/− | −/− |
| Example 5 | CT | −/− | pectin | 0.7 +/− 0.1 | n.a. | metal | 3.5 ± 0.4 | 0.28 ± 0.03 | −/− | −/− | −/− |
| Example 6 | CT | −/− | chitosan | 0.2 | n.a. | metal | 2.2 ± 0.2 | 2.7 ± 0.3 | −/− | −/− | −/− |
| Example 7 | CT | −/− | pullulan | 0.2 | n.a. | metal | 1.4 ± 0.15 | 5.0 ± 0.5 | −/− | −/− | −/− |
| Example 8 | CT | −/− | pectin | 0.7 +/− 0.1 | n.a. | AIOx | 4.6 ± 0.4 | 0.27 ± 0.02 | −/− | −/− | −/− |
| Example 9 | CT | −/− | chitosan | 0.2 | n.a. | AIOx | 0.5 ± 0.1 | 2.8± 0.3 | −/− | −/− | −/− |
| Example 10 | CT | −/− | pullulan | 0.2 | n.a. | AIOx | 0.7 ± 0.05 | 4.9± 0.5 | −/− | −/− | −/− |
| Non-coated | −/− | −/− | −/− | −/− | −/− | −/− | −/− | 2170 | n.a. | 5.2 | n.a. |
| substrate | | | | | | | | | | | |
| Comparative | −/− | −/− | pectin | n.a. | | −/− | −/− | does not spread properly | | | |
| Example 1 | | | | | | | | | | | |
| Example 11 | −/− | PEI, 0.1 | pectin | 0.9 ± 0.1 | TBD | −/− | −/− | 1.61 | 2.57 | 7.4 | 7.8 |
| Non-coated | −/− | −/− | −/− | −/− | | −/− | −/− | 1100 | n.a. | 440 | n.a. |
| substrate | | | | | | | | | | | |
| Comparative | −/− | −/− | pectin | n.a. | | −/− | −/− | does not spread properly | | | |
| Example 2 | | | | | | | | | | | |
| Example 12 | −/− | PEI, 0.1 | pectin | 0.9 ± 0.1 | TBD | −/− | −/− | 0.11 | 0.96 | Too | Too |
| | | | | | | | | | | high | high |
| Non-coated | −/− | −/− | −/− | −/− | −/− | −/− | −/− | 350 | n.a. | 5.5 | n.a. |
| substrate | | | | | | | | | | | |
| Example 13 | CT | −/− | pectin | 0.2 | 4.1/3.6 | −/− | −/− | 0.11 | 0.11 | n.a. | n.a. |
| Comparative | −/− | −/− | pectin | n.a. | n.a. | −/− | −/− | does not spread properly | | | |
| Example 3 | | | | | | | | | | | |
| Example 14 | −/− | PEI, 0.1 | pectin | 0.9 ± 0.1 | TBD | −/− | −/− | 0.08 | 0.05 | 8.87 | 8.7 |
| Non-coated | AIOx with | −/− | −/− | −/− | −/− | −/− | −/− | 140 | 250 | 1.2 | 0.16 |
| substrate | plasma | | | | | | | | | | |
| Example 15 | ″ | −/− | pectin | 0.9 ± 0.1 | TBD | −/− | −/− | 8.11 | 6.67 | 0.57 | 0.99 |
| Example 16 | ″ | PEI, 0.1 | pectin | 0.9 ± 0.1 | TBD | −/− | −/− | 0.16 | 1.15 | n.a. | n.a. |

Legend:
CT = corona treatment
−/− = no results available
TBD = to be done
⁺ ) Adhesion determined by 3M . . . tape peel test on biopolymer coated multilayer film with coat weight of 0.2 g/m2 dry. “Passed”= the biopolymer coating could not be peeled off.

While the invention has been described in detail and with reference to specific examples thereof, it will be apparent to one skilled in the art that various changes and modifications can be made therein without departing from the spirit and scope thereof.

What is claimed is:

1. A multilayer film comprising:
a substrate film comprising an inner face, an outer face, a base film and optionally a metal or metal oxide barrier coating deposited on an outer face of the base film such that the outer face of the metal or metal oxide barrier coating forms the outer face of the substrate film; and
a biopolymer coating layer disposed on the outer face of the substrate film,
wherein the outer face of the substrate film has a surface tension suitable for adhesion to the biopolymer coating layer, and the multilayer film has at least one of gas barrier properties and vapor barrier properties.

2. The multilayer film of claim 1 wherein the biopolymer coating layer exhibits adhesion to the substrate film after a pre-treatment method selected from the group consisting of corona discharge, plasma treatment and flame treatment.

3. The multilayer film of claim 1, wherein the biopolymer coating layer exhibits adhesion to the substrate film after application of a primer.

4. The multilayer film of claim 1, wherein the multilayer film provides a barrier to permeation of gases selected from the group consisting of oxygen, nitrogen, carbon dioxide, moisture and combinations thereof.

5. The multilayer film of claim 1, wherein the multilayer film exhibits oxygen barrier and moisture barrier properties.

6. The multilayer film of claim 1, wherein the base film comprises a polymer selected from the group consisting of polyolefins, bioplastics, polyamides, polyesters, and layered combinations thereof.

7. The multilayer film of claim 1, wherein the base film comprises a polymer or polymer blend which is one or more polyolefins selected from the group consisting of polypropylene homopolymer, polyethylene including high density polyethylene, propylene/ethylene copolymers, propylene/ethylene/butene-1 terpolymers, maleated polypropylene, incompatible blends of polypropylene with polyethylene or another poly alpha-olefin, incompatible blends of polyethylene with another poly alpha-olefin, and combinations thereof.

8. The multilayer film of claim 1, wherein the base film comprises 1-7 coextruded layers, with at least one layer being polyamide or ethylene vinyl alcohol, and the majority of the coextruded layers comprising one or more polyolefins.

9. The multilayer film of claim 1, wherein the base film comprises at least one polyolefin layer, a tie layer adjacent to the at least one polyolefin layer and having an inside surface contiguous with an outside surface of the at least one polyolefin layer, and a polyamide layer contiguous with an outside surface of the tie layer.

10. The multilayer film of claim 1, wherein the base film comprises:
at least one core layer consisting essentially of polypropylene homopolymer;
an inner skin layer consisting of polypropylenes selected from the group consisting of propylene homopolymers, propylene copolymers, propylene terpolymers, maleated polypropylenes and blends thereof, wherein the inner skin layer is contiguous with an inner surface of the at least one core layer, optionally with an additional inner tie layer interjacent between the inner skin layer and the inner surface of the at least one core layer;
an outer tie layer consisting of maleated polypropylene or a blend of at least one polypropylene with polymers selected from the group consisting of maleated polypropylenes and copolymers of ethylene with at least one comonomer selected from the group consisting of vinyl acetate, methyl acrylate, butyl acrylate, vinyl alcohol and acrylic acid, wherein the outer tie layer is contiguous with an outer surface of the at least one core layer; and
an outer skin layer consisting of at least one polyamide selected from the group consisting of amorphous polyamides and semi-crystalline polyamides, wherein the outer skin layer is contiguous with an outer surface of the outer tie layer.

11. The multilayer film of claim 1, wherein the base film comprises one or more polymers selected from the group consisting of polyhydroxy alkanoates, polylactic acid (PLA), polyhydroxy alkanoates and polyesters comprising aliphatic diols and/or aliphatic dicarboxylic acids and copolymers thereof, cellulose-based bioplastics, starch, and combinations mixtures or blends thereof.

12. The multilayer film of claim 1, wherein the biopolymer coating layer comprises polysaccharides, polymeric sugar carboxylic acid, and chemically modified bio-based and/or biodegradable derivatives thereof.

13. The multilayer film of claim 1, wherein the biopolymer coating layer comprises polyuronic acid, polygalacturonic acid, and their chemically modified bio-based and/or biodegradable derivatives.

14. The multilayer film of claim 1, wherein the biopolymer coating layer comprises pectin, amidated pectin, methylated pectin, amidated and methylated pectin, pectin ester, pectin ester amide, pullulan, chitosan, and combinations thereof.

15. The multilayer film of claim 1, wherein the biopolymer coating layer comprises ethylenevinyl alcohol (EVOH) and/or polyvinyl alcohol (PVOH) as structuring agent, and/or a metal alkoxide as reinforcing agent.

16. The multilayer film of claim 1, wherein solvents selected from the group consisting of water, alcohols, ketones, and mixtures thereof are suitable to facilitate the application of the biopolymer coating to the substrate.

17. The multilayer film of claim 1, wherein water is a solvent effective to facilitate the application of the biopolymer coating.

18. The multilayer film of claim 1, wherein the biopolymer coating layer comprises amidated and/or methylated biopolymers of pectin.

19. The multilayer film of claim 1, wherein the biopolymer coating layer comprises esterified biopolymers of pectin.

20. The multilayer film of claim 1, wherein the biopolymer coating layer comprises esterified pectin, amidated pectin, methylated pectin, amidated and methylated pectin, esterified amidated pectin that contains methyl carboxylic groups, amide groups, and combinations thereof.

21. The multilayer film of claim 1, wherein the biopolymer coating layer comprises amidated pectin, methylated pectin, amidated, methylated pectin, and combinations thereof which have a degree of amidation from 15 to 65.

22. The multilayer film of claim 1, wherein the biopolymer coating layer comprises pectin with a degree of esterification from 7 to 75.

23. The multilayer film of claim 1, wherein the biopolymer coating layer comprises pectin which has a degree of esterification from 20 to 40, and a degree of amidation from 10 to 30.

24. The multilayer film of claim 1, wherein the biopolymer coating layer comprises pectin with about 30-40% of all carboxylate groups methylated and 10-20% amidated.

25. The multilayer film of claim 1, wherein the biopolymer coating layer comprises pectin with 40 to 60% of carboxylic acid groups being methylated and/or amidated.

26. The multilayer film of claim 1, wherein a metal layer is deposited on an outer face of the biopolymer coating layer.

27. The multilayer film of claim 26, wherein the metal layer is deposited on the outer face of the biopolymer coating layer using vacuum deposition technology.

28. The multilayer film of claim 1, wherein a metal oxide layer is deposited on an outer face of the biopolymer coating layer.

29. The multilayer film of claim 28, wherein the metal oxide layer is deposited on the outer face of the biopolymer coating layer using vacuum deposition technology.

30. The multilayer film of claim 1, wherein ink is disposed on the biopolymer coating layer.

31. The multilayer film of claim 1, wherein first a print primer, then inks are disposed on the biopolymer coating layer.

32. The multilayer film of claim 1, wherein the multilayer film comprises additional layers selected from the group consisting of metal, transparent metal oxide, additional protective coatings, printing, embossing, holographics, and combinations thereof.

33. The multilayer film of claim 1, wherein the multilayer film comprises additional alternating layers of metal or metal oxides and biopolymer.

34. The multilayer extruded film of claim 1, wherein the biopolymer coating layer provides for a function selected from the group consisting of adhesion, protection, barrier to permeation of gases, and combinations thereof.
